(19) United States
(12) Patent Application Publication
(10) Pub. No.: US 2015/0109016 A1
(43) Pub. Date: Apr. 23, 2015

(54) TEST PROBE CARD

(71) Applicant: STAr TECHNOLOGIES, INC., Hsinchu City (TW)

(72) Inventors: Choon Leong LOU, Hsinchu City (TW); Ho Yeh CHEN, Hsinchu City (TW)

(21) Appl. No.: 14/517,263

(22) Filed: Oct. 17, 2014

Related U.S. Application Data
(60) Provisional application No. 61/892,788, filed on Oct. 18, 2013.

(51) Int. Cl. G01R 31/26; G02B 6/43; G01R 1/073; G02B 6/42

(52) U.S. Cl. CPC G01R 31/2601; G02B 6/4295; G02B 6/43; G02B 6/4206; G01R 1/07307
USPC 324/756.03

(57) ABSTRACT

A test probe card adapted for testing a plurality of chips of a wafer is provided. The test probe card includes a substrate, a plurality of light-guiding elements, a plurality of lens units and a plurality of probes. The substrate has a plurality of through holes. Each of the through holes has a light entrance opening and a light exit opening. The light-guiding elements are disposed at the through holes, respectively. The lens units are disposed at the light exit openings, respectively. One end of each of the probes is electrically connected to the substrate and another end of each of the probes is adapted for electrically contacting one of the image sensing chips. Light emitted from a light source passes through one of the light-guiding elements and the lens element corresponding thereto in order and then is projected to one of the image sensing chips.

### CROSS REFERENCE TO RELATED APPLICATIONS

This application is based on and claims the benefit of priority from U.S. Provisional Application No. 61/892,788 filed on Oct. 18, 2013, which is incorporated herein by reference and assigned to the assignee herein.

### FIELD OF THE INVENTION

The present invention relates to a test probe card and particularly to a test probe card for testing a plurality of image sensing chips of a wafer.

### DESCRIPTION OF THE PRIOR ART

FIG. 1 is a schematic side view of a test probe card for testing a wafer according to the conventional art. Referring to FIG. 1, a conventional test probe card 100 is adapted for testing a plurality of image sensing chips 12 of a wafer 10. The wafer 10 has not yet been sawed, and thus the image sensing chips 12 have not yet been singulated.

The conventional test probe card 100 comprises a substrate 110, a plurality of lens units 120 and a plurality of probes 130. The substrate 110 has a plurality of through holes 112. Each of the through holes 112 has a light entrance opening 112a and a light exit opening 112b. The lens units 120 are disposed at the light exit openings 112b, respectively. One end of each of the probes 130 is electrically connected to the substrate 110, and another end of each of the probes 130 is adapted for electrically contacting one of the image sensing chips 12 (described later).

During a testing process, a light source of a testing machine (not shown) electrically connected to the substrate 110 emits light. The light passes through the through holes 112 of the substrate 110, and then is projected to the image sensing chips 12 by the lens units 120 with refractive power. During the testing process, if the image sensing chips 12 are good, a light sensing area 12a of each of the image sensing chips 12 senses the light projected by the corresponding lens unit 120 to convert a light signal into an electrical signal, and then the electrical signal is transmitted to the substrate 110 through the corresponding probes 130 in electrical contact with the image sensing chip 12.

However, due to the trend toward miniaturization and high integration of the image sensing chips 12, the distribution density of the through holes 112 increases and the cross-sectional area of each of the through holes 112 decreases. Hence, the range of light admitted to each of the lens units 120, i.e. the brightness of light admitted to each of the lens units 120 or the brightness of light incident to each of the lens units 120, is limited, and in consequence, during the testing process the brightness of the light projected to each of the image sensing chips 12 through the corresponding lens unit 120 decreases. Moreover, the light projected by the lens units 12 with refractive power is apt to cause chromatic dispersion and uneven distribution of brightness. As a result, the accuracy for testing each of the image sensing chips 12 cannot be ensured.

### SUMMARY OF THE INVENTION

The present invention provides a test probe card which comprises a light-guiding element for increasing the brightness of light admitted to the corresponding lens unit.

The present invention provides a test probe card which comprises a light-parallel-guiding element without any lens unit.

The present invention provides a test probe card adapted for testing a plurality of image sensing chips of a wafer. The test probe card comprises a substrate, a plurality of light-guiding elements, a plurality of lens units and a plurality of probes. The substrate has a plurality of through holes and each of the through holes has a light entrance opening and a light exit opening. The light-guiding elements are disposed at the through holes, respectively. The lens units are disposed at the light exit openings, respectively. One end of each of the probes is electrically connected to the substrate and another end of each of the probes is adapted for electrically contacting one of the image sensing chips. Light emitted from a light source is adapted for passing through one of the light-guiding elements and the lens element corresponding thereto in sequence and then is projected to one of the image sensing chips.

In an embodiment of the present invention, each of the light-guiding elements is a light diffuser.

In an embodiment of the present invention, each of the light-guiding elements is a light-parallel-guiding element for substantially parallel guiding the light emitted from the light source.

In an embodiment of the present invention, each of the light-guiding elements has a plurality of optical fibers, and each of the optical fibers extends in a direction running from the light entrance opening to the light exit opening of the corresponding through hole.

In an embodiment of the present invention, each of the light-guiding elements is disposed in the corresponding through hole.

The present invention provides a test probe card adapted for testing a plurality of image sensing chips of a wafer. The test probe card comprises a substrate, a plurality of light-parallel-guiding elements and a plurality of probes. The substrate has a plurality of through holes and each of the through holes has a light entrance opening and a light exit opening. The light-parallel-guiding elements are disposed at the through holes, respectively. One end of each of the probes is electrically connected to the substrate and another end of each of the probes is adapted for electrically contacting one of the image sensing chips. Light emitted from a light source is adapted for passing through one of the light-parallel-guiding elements and then is projected to one of the image sensing chips, and the light-parallel-guiding elements substantially parallel guide the light emitted from the light source.

In an embodiment of the present invention, each of the light-guiding elements has a plurality of optical fibers, and each of the optical fibers extends in a direction running from the light entrance opening to the light exit opening of the corresponding through hole.

In an embodiment of the present invention, part of each of the light-parallel-guiding elements is disposed in the corresponding through hole and another part of each of the light-parallel-guiding elements passes through the light exit opening of the corresponding through hole to protrude from the substrate.

The following description, the appended claims, and the embodiments of the present invention further illustrate the features and advantages of the present invention.

### BRIEF DESCRIPTION OF THE DRAWINGS

FIG. 1 is a schematic side view of a test probe card for testing a wafer according to the conventional art.

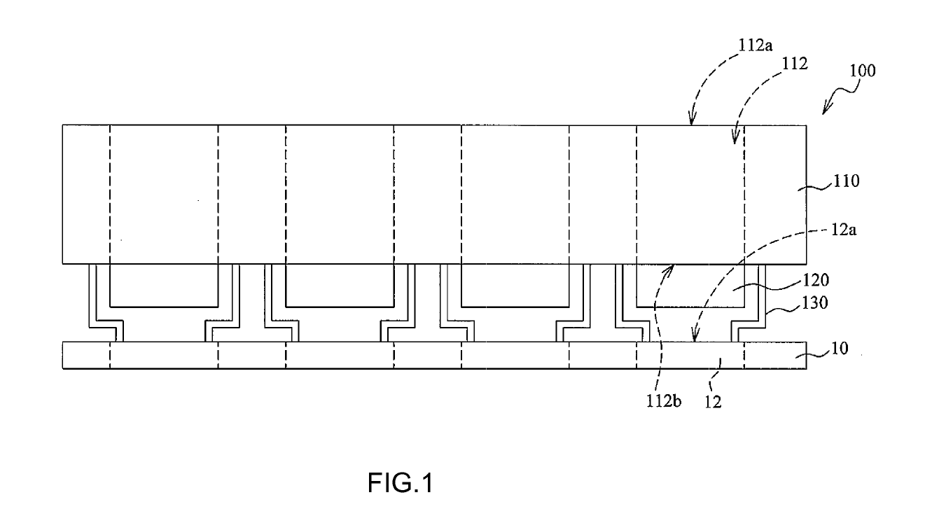

FIG. 2 is a schematic side view of a test probe card for testing a wafer according to a first embodiment of the present invention.

FIG. 3 is a schematic side view of a test probe card for testing a wafer according to a second embodiment of the present invention.

FIG. 4 is a schematic side view of a test probe card according to a third embodiment for testing a wafer of the present invention.

### DETAILED DESCRIPTION OF THE EMBODIMENTS

### First Embodiment

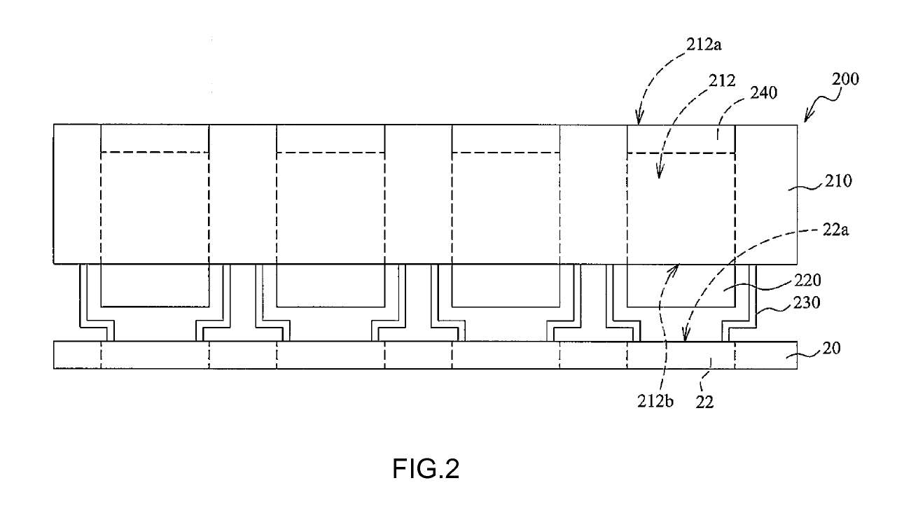

FIG. 2 is a schematic side view of a test probe card for testing a wafer according to a first embodiment of the present invention. Referring to FIG. 2, in the first embodiment, a test probe card 200 is adapted for testing a plurality of image sensing chips 22 of a wafer 20. The wafer 20 has not yet been sawed, and thus the image sensing chips 22 have not yet been singulated.

In the first embodiment, the test probe card 200 comprises a substrate 210 (such as a circuit board), a plurality of lens units 220, a plurality of probes 230, and a plurality of light-guiding elements 240. The substrate 210 has a plurality of through holes 212. Each of the through holes 212 has a light entrance opening 212a and a light exit opening 212b. The light-guiding elements 240 are disposed at the through holes 212, respectively. In the first embodiment, each of the light-guiding elements 240 is disposed in the corresponding through hole 212. The lens units 220 are disposed at the light exit openings 212b, respectively. One end of each of the probes 230 is electrically connected to the substrate 210, and another end of each of the probes 230 is adapted for electrically contacting one of the image sensing chips 22 (described later). In the first embodiment, each of the light-guiding elements 240 is, for example, a light diffuser (such as a diffusion plate) and disposed in the corresponding through hole 212.

During a testing process, a light source of a testing machine (not shown) electrically connected to the substrate 210 emits light. The light is guided by the light-guiding elements 240 such as the light diffusers while passing through the through holes 212 of the substrate 210, and then the light is projected to the image sensing chips 22 by the lens units 220 with refractive power. In other words, the light emitted from the light source is projected to one of the image sensing chips 22 through one of the light-guiding elements 240 and the lens unit 220 corresponding thereto in sequence. During the testing process, if the image sensing chips 22 are good, a light sensing area 22a of each of the image sensing chips 22 senses the light projected by the corresponding lens unit 220 to convert a light signal into an electrical signal, and then the electrical signal is transmitted to the substrate 210 through the corresponding probes 230 in electrical contact with the image sensing chip 22.

During the testing process, since the light is guided by the light-guiding elements 240 such as the light diffusers while passing through the through holes 212 of the substrate 210, the brightness of light admitted to each of the lens units 220 of the test probe card 200 in the first embodiment is effectively enhanced, as compared to the conventional test probe card 100.

### Second Embodiment

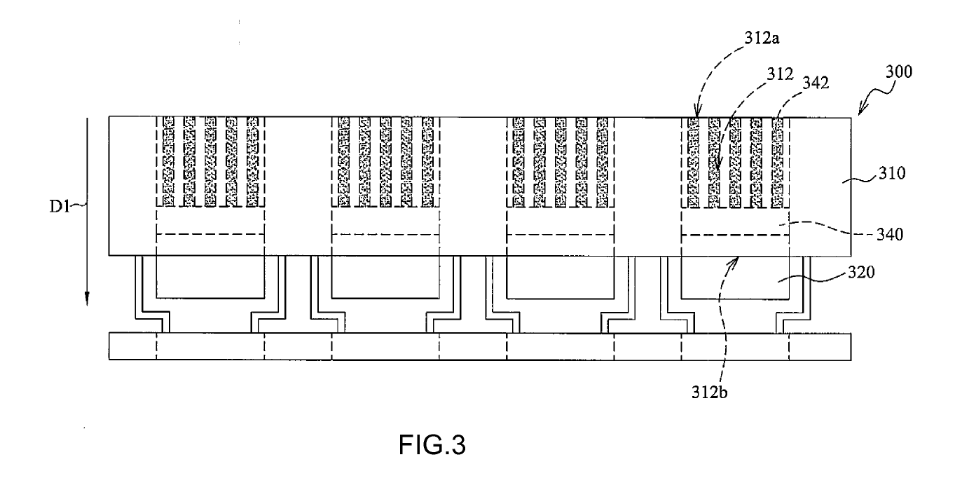

FIG. 3 is a schematic side view of a test probe card for testing a wafer according to a second embodiment of the present invention. Referring to FIG. 3, the difference between a test probe card 300 in the second embodiment and the test probe card 200 in the first embodiment lies in that in the second embodiment, each of light-guiding elements 340 of the test probe card 300 is a light-parallel-guiding element having a plurality of optical fibers 342, and each of the optical fibers 342 extends in a direction D1 running from a light entrance opening 312a to a light exit opening 312b of a corresponding through hole 312. In the second embodiment, the direction D1 is, for example, parallel to the axial direction of each of the through holes 312. In the second embodiment, each of the light-guiding elements 340 such as the light-parallel-guiding elements is disposed in the corresponding through hole 312.

During the testing process, light emitted from a light source of a testing machine (not shown) is substantially parallel guided by each of the light-guiding elements 340 such as the light-parallel-guiding elements. During the testing process, since the light is guided by the light-guiding elements 340 such as the light-parallel-guiding elements while passing through the through holes 312 of a substrate 310, the brightness of light admitted to each of lens units 320 of the test probe card 300 in the second embodiment is effectively enhanced, as compared to the conventional test probe card 100.

### Third Embodiment

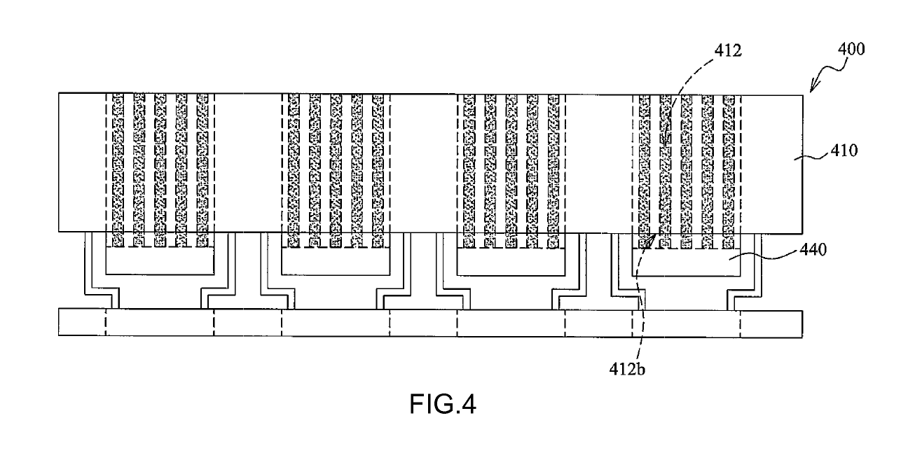

FIG. 4 is a schematic side view of a test probe card for testing a wafer according to a third embodiment of the present invention. Referring to FIG. 4, the difference between a test probe card 400 in the third embodiment and the test probe card 300 in the second embodiment is that the test probe card 400 in the third embodiment dispenses with the lens units 320 (see FIG. 3). In the third embodiment, part of each of light-parallel-guiding elements 440 is disposed in corresponding through hole 412. Another part of each of the light-parallel-guiding elements 440 penetrates a light exit opening 412b of the corresponding through hole 412 to protrude from a substrate 410. The structure of each of the light-parallel-guiding elements 440 in the third embodiment can be referred to the structure of each of the light-guiding elements 340 in the second embodiment and thus is not described in detail herein for the sake of brevity.

During the testing process, light emitted from a light source of a testing machine (not shown) is substantially parallel guided by each of the light-parallel-guiding elements 440. During the testing process, since the light is guided by the light-parallel-guiding elements 440 while passing through the through holes 412 of the substrate 410, brightness of light leaving each of the light-parallel-guiding elements 440 of the test probe card 400 in the third embodiment is effectively enhanced, as compared to the conventional test probe card 100. Moreover, the test probe card 400 in the third embodiment dispenses with any lens units, and thus light exiting from each of the light-parallel-guiding elements 440 of the test probe card 400 in the third embodiment is advantageously characterized by uniform distribution of brightness and little chromatic dispersion, as compared to the conventional test probe card 100.

Accordingly, test probe cards of the present invention have one of the following advantages or the other advantages. During the testing process, since light is guided by the light-guiding elements while passing through these through holes of the substrate according to each of the embodiments of the present invention, brightness of light admitted to each of the lens units of the test probe card in each of the embodiments of the present invention is effectively enhanced, as compared to the conventional test probe card. Furthermore, since the test probe card in an embodiment of the present invention can dispense with any lens units but has light-parallel-guiding elements, the light exiting from each of the light-parallel-guiding elements of the test probe card in the embodiment is advantageously characterized by uniform distribution of brightness and little chromatic dispersion, as compared to the conventional test probe card.

The foregoing detailed description of the embodiments is used to further clearly describe the features and spirit of the present invention. The foregoing description for each embodiment is not intended to limit the scope of the present invention. All kinds of modifications made to the foregoing embodiments and equivalent arrangements should fall within the protected scope of the present invention. Hence, the scope of the present invention should be explained most widely according to the claims described thereafter in connection with the detailed description, and should cover all the possibly equivalent variations and equivalent arrangements.

What is claimed is:

1. A test probe card, adapted for testing a plurality of image sensing chips of a wafer, comprising:
a substrate having a plurality of through holes, wherein each of the through holes has a light entrance opening and a light exit opening;
a plurality of light-guiding elements disposed at the through holes, respectively;
a plurality of lens units disposed at the light exit openings, respectively; and
a plurality of probes, wherein one end of each of the probes is electrically connected to the substrate and another end of each of the probes is adapted for electrically contacting one of the image sensing chips;
wherein light emitted from a light source is adapted for passing through one of the light-guiding elements and the lens element corresponding thereto in sequence and then is projected to one of the image sensing chips.

2. The test probe card of claim 1, wherein each of the light-guiding elements is a light diffuser.

3. The test probe card of claim 1, wherein each of the light-guiding elements is a light-parallel-guiding element for substantially parallel guiding the light emitted from the light source.

4. The test probe card of claim 3, wherein each of the light-guiding elements has a plurality of optical fibers, and each of the optical fibers extends in a direction running from the light entrance opening to the light exit opening of the corresponding through hole.

5. The test probe card of claim 1, wherein each of the light-guiding elements is disposed in the corresponding through hole.

6. A test probe card, adapted for testing a plurality of image sensing chips of a wafer, comprising:
a substrate having a plurality of through holes, wherein each of the through holes has a light entrance opening and a light exit opening;
a plurality of light-parallel-guiding elements disposed at the through holes, respectively; and
a plurality of probes, wherein one end of each of the probes is electrically connected to the substrate and another end of each of the probes is adapted for electrically contacting one of the image sensing chips;
wherein light emitted from a light source is adapted for passing through one of the light-parallel-guiding elements and then is projected to one of the image sensing chips, and the light-parallel-guiding elements substantially parallel guide the light emitted from the light source.

7. The test probe card of claim 6, wherein each of the light-parallel-guiding elements has a plurality of optical fibers, and each of the optical fibers extends in a direction running from the light entrance opening to the light exit opening of the corresponding through hole.

8. The test probe card of claim 6, wherein part of each of the light-parallel-guiding elements is disposed in the corresponding through hole and another part of each of the light-parallel-guiding elements passes through the light exit opening of the corresponding through hole to protrude from the substrate.
